(19) United States
(12) Patent Application Publication
(10) Pub. No.: US 2008/0038881 A1
(43) Pub. Date: Feb. 14, 2008

(54) Thin Film Transistor Array Panel and Manufacturing Method Thereof

(76) Inventors: Jung-Han Shin, Yongin-si (KR); Joon-Hak Oh, Yongin-si (KR); Min-Ho Yoon, Seoul (KR)

Correspondence Address: Frank Chau, Esq.;F. CHAU & ASSOCIATES, LLC, 130 Woodbury Road, Woodbury, NY, 11797, US

(21) Appl. No.: 11/621,807

(22) Filed: Jan. 10, 2007

(30) Foreign Application Priority Data
Aug. 8, 2006 (KR) 10-2006-0074646

(51) Int. Cl. H01L 21/84

(52) U.S. Cl. 438/149

(57) ABSTRACT

A thin film transistor array panel according to an embodiment of the present invention includes a gate electrode, a source electrode and a drain electrode opposing each other and separated from each other on the gate electrode. An organic semiconductor is in contact with the source electrode and the drain electrode. A gate insulator is formed between the gate electrode and the organic semiconductor. A pixel electrode is connected to the drain electrode. A passivation member covers the organic semiconductor and includes a nonionic soluble polymer.

### CROSS-REFERENCE TO RELATED APPLICATION

This application claims priority to Korean Patent Application No. 10-2006-0074646 filed in the Korean Intellectual Property Office on Aug. 8, 2006, the entire contents of which are incorporated herein by reference.

### BACKGROUND OF THE INVENTION

1. Technical Field

The present invention relates to a transistor panel and more particularly to a thin film transistor array panel and a manufacturing method thereof.

2. Discussion of the Related Art

Generally, a flat panel display, such as a liquid crystal display (LCD), an organic light emitting diode (OLED) display, and an electrophoretic display, includes a pair of electric-field generating electrodes and an electro-optical active layer disposed therebetween. The LCD includes a liquid crystal layer as the electro-optical active layer, and the OLED display includes an organic light emitting layer as the electro-optical active layer.

One of the pair of field generating electrodes is usually coupled with a switching element to receive electrical signals. The electro-optical active layer converts the electrical signals into optical signals to display images.

The switching element for the flat panel display includes a thin film transistor (TFT) having three terminals and gate lines transmitting control signals for controlling the TFTs. Data lines transmit data signals to be supplied to the pixel electrodes through the TFTs.

Among the TFTs, organic thin film transistors (OTFTs) are being developed. An OTFT includes an organic semiconductor instead of an inorganic semiconductor such as Si.

Because the OTFT may be manufactured by a solution process at a low temperature, it may be adapted to a flat panel display with large size, which need not be manufactured by a deposition process. Also, because the organic material is made of patterns such as a fiber or a film, the OTFT is used as the core element of a flexible display device.

However, because the organic semiconductor may have less thermal resistance and chemical resistance than the inorganic semiconductor, the organic semiconductor may be damaged in the manufacturing process. Accordingly, the structure and manufacturing method of the OTFT is different from those of the inorganic semiconductor TFT, for example, the number of masks used in the manufacturing method of the OTFT and the production cost are increased. In particular, an additional protection member for protecting the organic semiconductor is needed and the mask for forming the protection member is added.

### SUMMARY OF THE INVENTION

Exemplary embodiments of the present invention provide a thin film transistor array panel and a method for manufacturing the same. The panel comprises a protection member without requiring the use of an additional mask. Therefore, the number of masks needed to manufacture the panel are minimized.

A thin film transistor array panel according to an exemplary embodiment of the present invention includes a gate electrode, a source electrode, and a drain electrode opposing each other and separated from each other on the gate electrode. An organic semiconductor is in contact with the source electrode and the drain electrode. A gate insulator is formed between the gate electrode and the organic semiconductor. A pixel electrode is connected to the drain electrode. A passivation member covers the organic semiconductor and includes a nonionic soluble polymer.

The nonionic soluble polymer may comprise polyvinyl alcohol (PVA), polyvinyl pyrrolidone (PVP), polyethylene glycol, and/or derivatives thereof.

The thin film transistor array panel may further comprise a gate line connected to the gate electrode. A data line is connected to the source electrode. An interlayer insulating layer is formed on the gate line and the data line. The interlayer insulating layer has a first opening exposing the gate electrode. The gate insulator is disposed in the first opening.

The thin film transistor array panel may further comprise a bank formed on the source electrode and the drain electrode. The panel may have a second opening exposing a portion of the source electrode and the drain electrode. The organic semiconductor is disposed in the second opening.

The second opening is smaller than the first opening.

The gate insulator and/or the organic semiconductor comprises a soluble material.

The source electrode and the drain electrode comprise indium tin oxide (ITO) or indium zinc oxide (IZO).

A method for manufacturing a thin film transistor array panel is provided which includes forming a gate electrode, source electrode, and a drain electrode opposing each other and separated from each other on the gate electrode. A gate insulator is formed on the gate electrode. An organic semiconductor is formed on the gate insulator. A passivation member covering the organic semiconductor is formed. To form the passivation member, an insulating solvent including a nonionic soluble polymer and a polarity solvent is formed and dried.

The nonionic soluble polymer may comprise polyvinyl alcohol (PVA), polyvinyl pyrrolidone (PVP), polyethylene glycol, and/or derivatives thereof.

The polarity solvent may comprise water, alcohol, and/or ammonia dissolved in water.

The nonionic soluble polymer may be contained in the insulating solvent within the range of 0.1 to 10 percent by weight.

The viscosity of the insulating solution may be within the range of about 1 to about 15 centipoise (cP).

The gate insulator and/or the organic semiconductor may be formed by inkjet printing.

The source electrode and the drain electrode comprise ITO or IZO. The ITO or IZO may be deposited at a low temperature of about 25 to about 100° C. An etchant for ITO or IZO includes a weak alkaline etchant.

### BRIEF DESCRIPTION OF THE DRAWINGS

Exemplary embodiments of the present invention will become more apparent by describing the exemplary embodiments in detail with reference to the accompanying drawings, in which:

FIG. 1 is a layout view of an organic thin film transistor (TFT) array panel according to an exemplary embodiment of the present invention;

FIG. 2 is a sectional view of the organic TFT array panel shown in FIG. 1 taken along line II-II;

FIGS. 3, 5, 7, 9, and 11 are layout views of the organic TFT array panel shown in FIGS. 1 and 2 during intermediate steps of a manufacturing method thereof according to an exemplary embodiment of the present invention;

FIG. 4 is a sectional view of the TFT array panel shown in FIG. 3 taken along line III-III;

FIG. 6 is a sectional view of the TFT array panel shown in FIG. 5 taken along line V-V;

FIG. 8 is a sectional view of the TFT array panel shown in FIG. 7 taken along line VIII-VIII;

FIG. 10 is a sectional view of the TFT array panel shown in FIG. 9 taken along line IX-IX; and

FIG. 12 is a sectional view of the TFT array panel shown in FIG. 11 taken along line XII-XII.

### DETAILED DESCRIPTION OF EXEMPLARY EMBODIMENTS

Exemplary embodiments of the present invention are described in detail herein with reference to the accompanying drawings. In the drawings, the thickness of layers and regions may be exaggerated for clarity and like numerals refer to like elements throughout. When an element such as a layer, region, or substrate is referred to as being “on” another element, it can be directly on the other element or intervening elements may also be present.

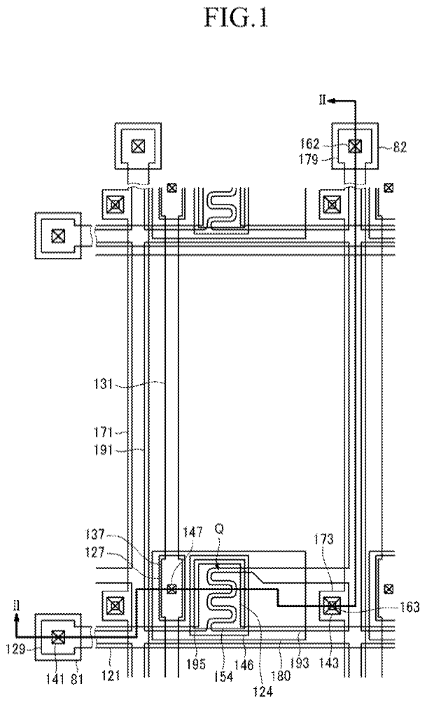

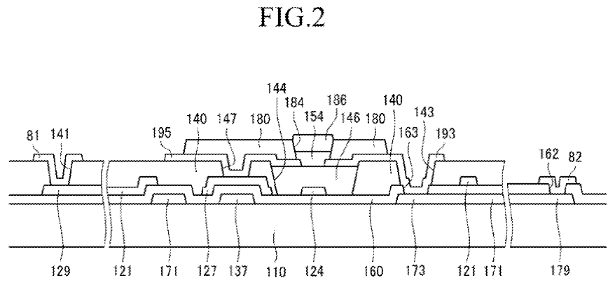

An organic thin film transistor array panel according to an exemplary embodiment of the present invention will be described in detail with reference to FIGS. 1 and 2.

FIG. 1 is a layout view of an organic thin film transistor array panel according to an exemplary embodiment of the present invention, and FIG. 2 is a sectional view of the organic TFT shown in FIG. 1 taken along line II-II.

A plurality of data lines 171 and a plurality of storage electrode lines 131 are formed on an insulating substrate 110 made of a material such as transparent glass, silicone, or plastic.

The data lines 171 transmit data signals and extend substantially in a longitudinal direction. Each data line 171 includes a plurality of projections 173 protruded therefrom, and an end portion 179 having a large area for contact with another layer or an external driving circuit. A data driving circuit (not shown) for generating the data signals may be mounted on a flexible printed circuit (FPC) film (not shown), which may be attached to the substrate 110, directly mounted on the substrate 110, or integrated with the substrate 110. The data lines 171 may extend to connect to a driving circuit that may be integrated with the substrate 110.

The storage electrode lines 131 transmit a predetermined voltage such as a common voltage and extend in the longitudinal direction. Each storage electrode line 131 is disposed between two adjacent data lines 171 and is closer to the left one of the two data lines 171, and includes a plurality of storage electrodes 137 extended therefrom. The storage electrode lines 131 may have various shapes and arrangements.

The data lines 171 and storage electrode lines 131 may be made of a metal including Al or an Al alloy, Ag or an Ag alloy, Au or a Au alloy, Cu or a Cu alloy, Mo or a Mo alloy, Cr, Ta, Or Ti. The conductors may have a multi-layered structure including two conductive films (not shown) having different physical characteristics.

The lateral sides of the data lines 171 and the storage electrode lines 131 are inclined relative to a surface of the substrate 110, and the inclination angle thereof ranges from about 30 to about 80 degrees.

A lower interlayer insulating layer 100 is formed on the data lines 171 and storage electrode lines 131. The lower interlayer insulating layer 160 may be made of an inorganic insulator such as silicon nitride (SiNx) and silicon oxide (SiOx), or an organic insulating material. The thickness of the lower interlayer insulating layer 160 may be in the range of about 2,000 to about 5,000 angstroms.

The lower interlayer insulating layer 160 has a plurality of contact holes 162 exposing the end portions 179 of the data lines 171 and a plurality of contact holes 163 exposing the projections 173 of the data lines 171.

A plurality of gate lines 121 and a plurality of storage capacitor conductors 127 are formed on the lower interlayer insulating layer 160.

The gate lines 121 transmit gate signals and extend substantially in a transverse direction. Each of the gate lines 121 intersects the data lines 171 and the storage lines 131 and includes a plurality of gate electrodes 124 projecting upward, and an end portion 129 having a large area for contact with another layer or an external driving circuit. A gate driving circuit (not shown) for generating the gate signals may be mounted on an FPC film (not shown), which may be attached to the substrate 110, directly mounted on the substrate 110, or integrated with the substrate 110. The gate lines 121 may extend to connect to a driving circuit that may be integrated on the substrate 110.

The storage capacitor conductors 127 are separated from the gate lines 121 and overlap the storage electrodes 137.

The gate lines 121 and the storage capacitor conductors 127 may be made of a conductor material having low resistivity. The data lines 171 and the storage electrode lines 131 may also be made of a conductor material having a low resistivity.

The lateral sides of the gate lines 121 and the storage capacitor conductors 127 are inclined relative to a surface of the substrate 110, and their inclination angles range from about 30 to about 80 degrees.

An upper interlayer insulating layer 140 is formed on the gate lines 121 and the storage capacitor conductors 127. The upper insulating layer 140 may be made of a material that may be formed by a solvent process, such as a photosensitive organic material. The thickness of the upper interlayer insulating layer 140 may be in the range of about 5,000 angstroms to about 4 microns.

The portion of the upper interlayer insulating layer 140 neighboring the end portion 179 is removed to present poor adhesion between the upper interlayer insulating layer 140 and the lower interlayer insulating layer 160 and to effectively connect the end portion 179 of the data line 171 on the external circuit while reducing the thickness of the interlayer insulating layer.

The upper interlayer insulating layer 140 has a plurality of openings 144 exposing the gate electrodes 124, a plurality of contact holes 141 exposing the end portions 129 of the gage lines 121, a plurality of contact holes 143 exposing the projections 173 of the data lines 171 through the contact holes 163, and a plurality of contact holes 147 exposing the storage capacitor conductors 127.

A plurality of gate insulators 146 are formed in the openings 144 of the upper interlayer insulating layer 140. The gate insulators 146 cover the gate electrodes 124, and the thickness of the gate insulators 146 is in the range of about 1,000 to about 10,000 angstroms. Because the side walls of the openings 144 are higher than the thickness of the gate insulators 146, the upper interlayer insulating layer 140 is banked. The openings 144 may have sufficient size for the gate insulators 146 to have flat surfaces.

The gate insulators 146 may be made of, or from derivatives of, polyacryl, polystyrene, polyimide, polyvinyl alcohol, parylene, perfluorocyclobutane, perfluorovinylether, and/or benzocyclobutane (BCB).

A plurality of source electrodes 193, a plurality of pixel electrodes 191, and a plurality of contact assistants 81 and 82 are formed on the upper interlayer insulating layer 140 and the gate insulators 146. They may be made of ITO and/or IZO, and may have thickness in the range of about 200 to about 2,000 angstroms.

The source electrodes 193 are electrically connected to the data lines 171 through the contact holes 143 and 163 and extended to the upper portion of the gate electrodes 124.

Each pixel electrode 191 includes a portion 195 disposed opposite a source electrode 193 with respect to a gate electrode 124. This portion 195 of the pixel electrode 191 is referred to as the drain electrode 195, and is connected to a storage capacitor conductor 127 through a contact hole 147.

The pixel electrodes 191 overlap the gate lines 121 and the data lines 171 to increase the aperture ratio.

The drain electrodes 195 and the source electrodes 193 have serpentine edges that face each other. The edges may be separated from each other by a distance that remains substantially constant for each pair of drain-source electrodes.

The contact assistants 81 and 82 are connected to the end portions 129 and 179 of the gate lines 121 and the data lines 171 through the contact holes 141 and 162. The contact assistants 81 and 82 protect the end portions 129 and 179 and enhance the adhesions between the end portions 129 and 179 and external devices.

A plurality of banks 180 are formed on the source electrode 193, the pixel electrodes 191, and the upper interlayer insulating layer 140. The banks 180 have a plurality of openings 184 disposed on the gate electrode 124 and the openings 144 of the upper interlayer insulating layer 140 for exposing portions of the source electrodes 193 and the drain electrodes 195, and the portions of the gate insulators 146 therebetween.

The banks 180 may be made of a photosensitive organic material that may be formed by a solvent process, and may have a thickness of about 5,000 angstroms to about 4 microns. The openings 184 are smaller than the openings 144 of the upper interlayer insulating layer 140 such that the banks 180 are solidly fixed to the gate insulators 146 to prevent them from lifting and penetration of the chemical solvent may be prevented in the manufacturing process.

A plurality of organic semiconductor islands 154 are placed in the openings 184 of the banks 180. The organic semiconductor islands 154 are disposed on the gate electrodes 124 and contact the source electrodes 193 and the drain electrodes 195. Because the height of the organic semiconductor islands 154 is smaller than that of the banks 180, the organic semiconductor islands 154 are completely enclosed by the banks 180. Since the lateral surfaces of the organic semiconductor islands 154 are not exposed, chemicals used in later process steps are prevented from infiltrating the organic semiconductor islands 154.

The organic semiconductor islands 154 may include a high molecular compound or a low molecular compound, which is soluble in an aqueous solution or organic solvent. In this case, the organic semiconductor islands 154 can be formed by printing, for example, by inkjet printing. However, the organic semiconductor islands 154 may alternatively be formed by deposition or a solution process including spin or slit coating and by lithography with or without etching. The organic semiconductor islands 154 may be made of, or from precursors of, pentacene. Alternatively the organic semiconductor islands 154 may be made of, or from derivatives of, tetrabenzoporphyrin, polyphenlenevinylene, polyfluorene, polythienylenevinylene, polythiophene, polythienothiophene, polyarylamine, and/or phthalocyanine.

The organic semiconductor islands 154 may be made of poly 3-hexylthiophene, metalized phthalocyanine and/or halogenated derivatives thereof, perylene tetracarboxylic dianhydride (PTCDA), naphthalene tetracarboxylic dianhydride (NTCDA), and/or their imide derivatives. Alternatively, the organic semiconductor islands 154 may also be made of perylene, coronene, or derivatives thereof with a substituent.

A plurality of passivation members 186 are formed on the organic semiconductor islands 154 and may have a flat top surface. The passivation members 186 may be made of an insulating material such as nonionic soluble polymer. Examples of such a material are polyvinyl alcohol (PVA), polyvinyl pyrrolidone (PVP), polyethylene glycol, and derivatives thereof. The passivation members 186 protect the organic semiconductor islands 154 from being damaged by external heat, plasma, or chemical materials in the manufacturing process.

A gate electrode 124, a source electrode 193, a drain electrode 195, and an organic semiconductor island 154 comprise an organic TFT Q. The TFT Q has a channel formed in the organic semiconductor island 154 disposed between the source electrode 193 and the drain electrode 195.

The pixel electrodes 191 receive data voltages from the organic TFT Q and generate an electric field in conjunction with a common electrode (not shown) of an opposing display panel (not shown). The display panel is supplied with a common voltage which determines the orientation of liquid crystal molecules (not shown) in a liquid crystal (not shown) disposed between the two electrodes. A pixel electrode 191 and the common electrode from a capacitor referred to as a “liquid crystal capacitor,” which stores applied voltages even after the organic TFT turns off.

An additional capacitor called a “storage capacitor,” which is connected in parallel to the liquid crystal capacitor, is provided for enhancing the voltage storing capacity. The storage capacitors are implemented by overlapping the pixel electrodes 191 and the storage capacitor conductors 127 connected thereto with the storage electrode lines 131 including the storage electrodes 137.

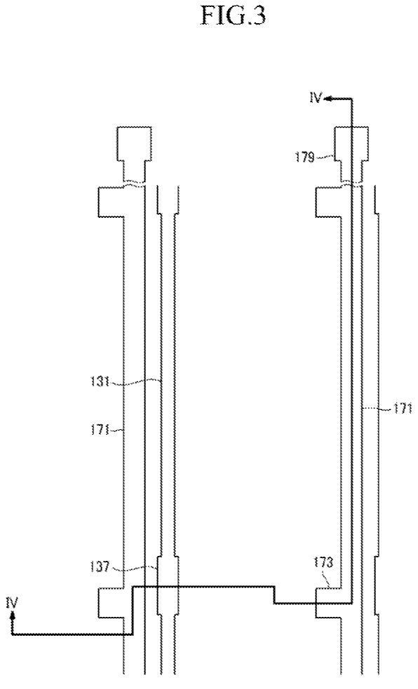

A method of manufacturing the LCD shown in FIGS. 1 and 3 according to an exemplary embodiment of the present invention will be described in detail with reference to FIGS. 3 to 12.

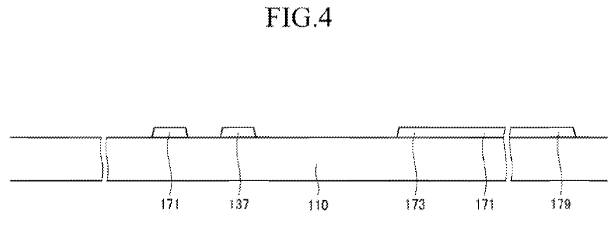

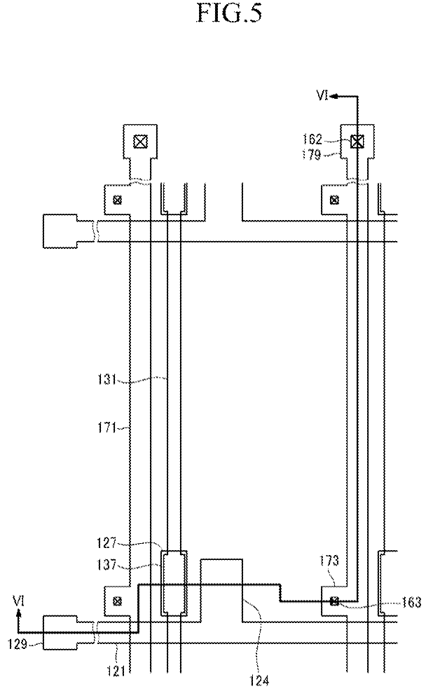

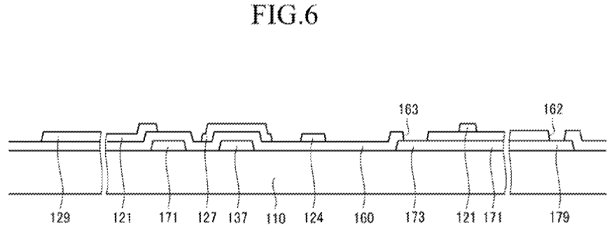

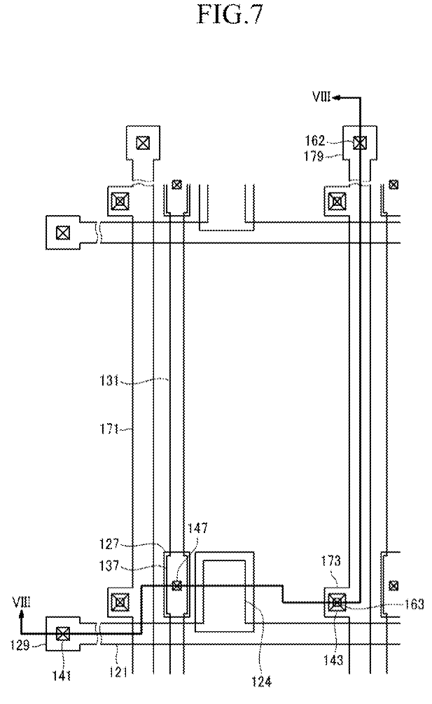

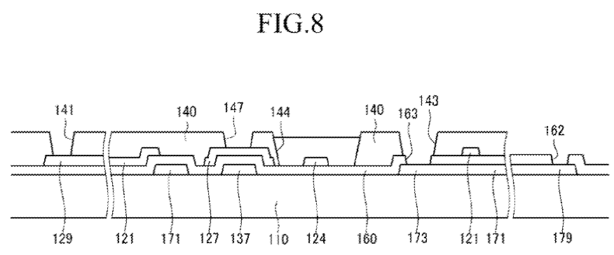

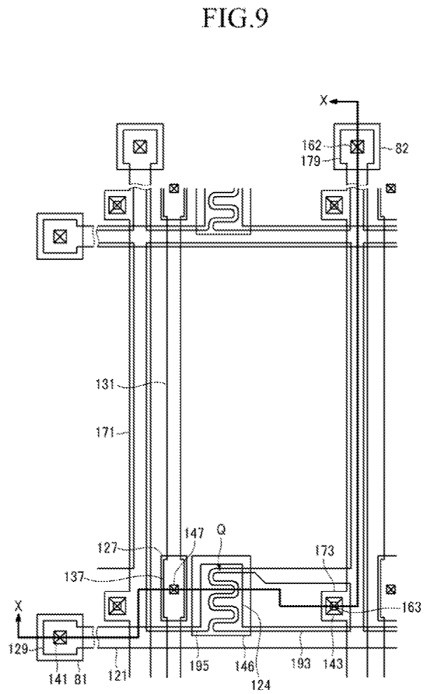

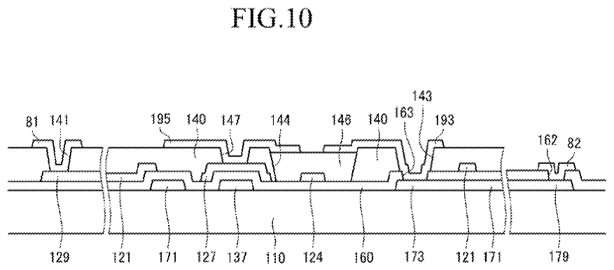

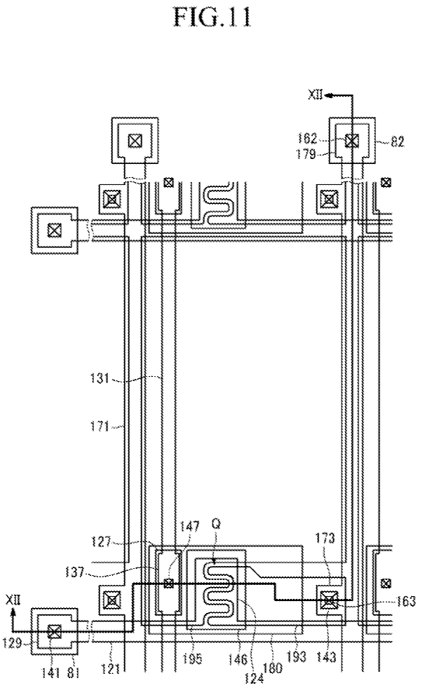

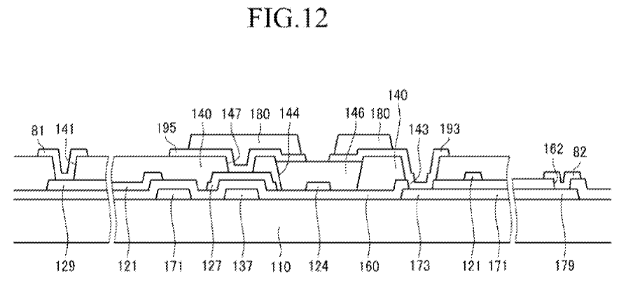

FIGS. 3, 5, 7, 9 and 11 are layout views of the organic TFT array panel shown in FIGS. 1 and 2 during intermediate steps of a manufacturing method thereof according to an exemplary embodiment of the present invention. FIG. 4 is a sectional view of the TFT array panel shown in FIG. 3 taken along line III-III. FIG. 6 is a sectional view of the TFT array panel shown in FIG. 5 taken along line V-V. FIG. 8 is a sectional view of the TFT array panel shown in FIG. 7 taken along line VIII-VIII. FIG. 10 is a sectional view of the TFT array panel shown in FIG. 9 taken along line IX-IX. FIG. 12 is a sectional view of the TFT array panel shown in FIG. 11 taken along line XII-XII.

Referring to FIGS. 3 and 4, a conductive layer is deposited on a substrate 110 by sputtering, etc., and is patterned by lithography and etched to form a plurality of data lines 171 including projections 173 and end portions 179, and a plurality of storage electrode lines 131 including a plurality of storage electrodes 137.

Referring to FIGS. 5 and 6, a lower interlayer insulating layer 160 having a plurality of contact holes 163 and 162 is deposited. The lower interlayer insulating layer 160 may be made of an inorganic material and may be deposited by chemical vapor deposition (CVD), etc. The lower interlayer insulating layer 160 may alternatively be made of an organic material and deposited, for example, by spin coating. The lower interlayer insulating layer 160 may be made by an imprinting transfer etch process.

Next, a conductive layer, made as Al or an Al alloy, is deposited on the substrate 110 by using sputtering, etc., and is patterned by lithography and etched to form a plurality of gate lines 121 including the gate electrodes 124 and end portions 129, and a plurality of storage capacitor conductors 127.

Referring to FIGS. 7 and 8, a photosensitive organic material is spin coated and patterned to form an upper interlayer insulating layer 140 having a plurality of openings 144 and a plurality of contact holes 143, 141, and 147. Here, the organic material neighboring the end portions 129 of the gate lines 121 is removed.

Next, a plurality of gate insulators 146 are formed in the openings 144 of the upper interlayer insulating layer 140 by inkjet printing an organic insulating solvent in the openings 144 and thermal treatment. Alternatively, various solvent processes such as spin coating, slit coating, microcontact printing, and spray printing may be used.

Referring to FIGS. 9 and 10, an amorphous ITO layer is deposited and patterned by lithography and wet etched with an etchant to form a plurality of source electrodes 193, a plurality of pixel electrodes 191 including drain electrodes 195, and a plurality of contact assistants 81 and 82.

The deposition of the amorphous ITO layer or IZO layer may be performed at a low temperature of about 25 to about 100° C., for example, at room temperature. The etchant for the amorphous ITO layer or IZO layer may include a weak alkaline etchant to reduce damage to the gate insulators 146 and the upper interlayer insulating layer 160. The upper interlayer insulating layer 160 may be made of an organic material by heat or a chemical solvent. The ITO layer or the IZO layer may be annealed. Alternatively, the anneal process may be omitted.

Referring to FIGS. 11 and 12, a photosensitive organic material is coated and developed to form a plurality of banks 180 including a plurality of openings 184.

Referring to FIGS. 1 and 2, a plurality of semiconductor islands 154 are formed in the openings 184. The semiconductor islands 154 may be formed by a solvent process such as an inkjet printing method.

A plurality of passivation members 186 are sequentially formed on the semiconductor islands 154. The semiconductor islands 154 may be formed by a solvent process such as an inkjet printing method.

To form the passivation members 186, an insulating solvent, such as non-ionic soluble polymer, including a polarity solvent is formed.

Examples of such a nonionic soluble polymer are polyvinyl alcohol (PVA), polyvinyl pyrrolidone (PVP), polyethylene glycol, and derivatives thereof.

Examples of such a polarity solvent are water, alcohol, and ammonia dissolved in water.

The nonionic soluble polymer may be contained in the insulating solvent within the range of 0.1 to 10 percent by weight and the viscosity of the insulating solution is in the range of about 1 to about 15 centipoise (cP). The passivation members 186 may be un-uniform due to having a viscosity less than about 1 centipoise (cP). The spray nozzle for the insulating solvent may be blocked due to pollution of the inkjet head under a viscosity more than about 15 centipoise (cP).

The insulating solution is dried to form the passivation members 186 completely covering the organic semiconductor islands 154.

The passivation members 186 protect the organic semiconductor islands 154 from being damaged by external heat, plasma, or chemical materials in the manufacturing process. Accordingly, the deterioration of the organic TFT may be prevented.

Furthermore, the passivation members 186 are formed without an additional mask, and photolithography process by spraying the insulating material. The insulating material may be, for example, a nonionic soluble polymer or an insulating solvent including a polarity solvent. Accordingly, the process cost and the process time may be decreased.

According to some exemplary embodiments of the present invention, the passivation members covering the organic semiconductors are formed without an additional mask and photolithography process. Accordingly, the process cost and the process time may be decreased and the deterioration of the organic TFT may be prevented.

Although exemplary embodiments of the present invention have been described in detail hereinabove, it should be clearly understood that many variations and/or modifications of the basic concepts described herein may appear to those skilled in the present art to fall within the spirit and scope of the present disclosure.

What is claimed is:

1. A thin film transistor array panel comprising:
a gate electrode;
a source electrode and a drain electrode on the gate electrode, the source electrode and the drain electrode opposing each other and separated from each other;
an organic semiconductor in contact with the source electrode and the drain electrode;
a gate insulator formed between he gate electrode and the organic semiconductor;
a pixel electrode connected to the drain electrode; and
a passivation member covering the organic semiconductor and comprising a nonionic soluble polymer.

2. The thin film transistor array panel of claim 1, wherein the nonionic soluble polymer is at least one member of the group consisting of polyvinyl alcohol (PVA), polyvinyl pyrrolidone (PVP), polyethylene glycol, or derivatives thereof.

3. The thin film transistor array panel of claim 2, further comprising:
a gate line connected to the gate electrode;
a data line connected to the source electrode; and
an interlayer insulating layer formed on the gate line and the data line and having a first opening exposing the gate electrode,
wherein the gate insulator is disposed in the first opening.

4. The thin film transistor array panel of claim 3, further comprising:
a bank formed on the source electrode and the drain electrode and having a second opening exposing a portion of the source electrode and the drain electrode,
wherein the organic semiconductor is disposed in the second opening.

5. The thin film transistor array panel of claim 4, wherein the second opening is smaller than the first opening.

6. The thin film transistor array panel of claim 1, wherein at least of the gate insulator and the organic semiconductor comprise a soluble material.

7. The thin film transistor array panel of claim 1, wherein the source electrode and the drain electrode each comprise ITO or IZO.

8. A method for manufacturing a thin film transistor array panel comprising:
forming a gate electrode;
forming a source electrode and a drain electrode on the gate electrode, the source electrode and the drain electrode opposing each other and separated from each other;
forming a gate insulator on the gate electrode;
forming an organic semiconductor on the gate insulator; and
forming a passivation member covering the organic semiconductor,
wherein, forming the passivation member comprises forming and drying an insulating solvent comprising a nonionic soluble polymer and a polarity solvent.

9. The method of claim 8, wherein the nonionic soluble polymer is at least one member of the group consisting of polyvinyl alcohol (PVA), polyvinyl pyrrolidone (PVP), polyethylene glycol, or derivatives thereof.

10. The method of claim 9, wherein the polarity solvent is at least one member of the group consisting of water, alcohol, or ammonia dissolved in water.

11. The method of claim 8, wherein the insulating solvent comprises nonionic soluble polymer in the range of about 0.1 to about 10 percent by weight.

12. The method of claim 8, wherein the viscosity of the insulating solvent is in the range of about 1 to about 15 centipoise (cP).

13. The method of claim 8, wherein at least one of the gate insulator or the organic semiconductor is formed by using inkjet printing.

14. The method of claim 8, wherein the source electrode and the drain electrode each comprise ITO or IZO, the ITO or IZO is deposited at a low temperature of about 25 to about 100° C., and the ITO and IZO is patterned by lithography and wet etched with an etchant comprising a weak alkaline etchant.
